(19) United States
(12) Patent Application Publication
(10) Pub. No.: US 2026/0068088 A1
(43) Pub. Date: Mar. 5, 2026

(54) Methods, Devices, and Systems for Dissipating Heat at a Server System

(71) Applicant: Super Micro Computer, Inc., San Jose, CA (US)

(72) Inventors: Chia-Wei Chen, New Taipei City 235 (TW); Chieh Shih Yi, New Taipei City 235 (TW); Yaotsan Tsai, San Jose, CA (US); Kai Xiang Oh, San Jose, CA (US)

(21) Appl. No.: 18/824,727

(22) Filed: Sep. 4, 2024

(51) Int. Cl. H05K 7/20

(52) U.S. Cl. CPC H05K 7/20272; H05K 7/20781

(57) ABSTRACT

This application is directed to heat dissipation for a server system. A server rack includes a rack structure including a plurality of slots for receiving at least one or more rack servers. The server rack includes a first coolant distribution manifold coupled to a first front edge of the rack structure that extends adjacent to the plurality of slots. The first coolant distribution manifold includes a plurality of outlets configured to provide coolant flows to the one or more rack servers from the first front edge of the rack structure. The server rack further includes a second coolant distribution manifold coupled to a second front edge of the rack structure that extends adjacent to the plurality of slots. The second coolant distribution manifold includes a plurality of inlets configured to collect, from the second front edge of the rack structure, the coolant flows exiting the one or more rack servers.

### TECHNICAL FIELD

This application relates generally to cooling technology in electronic systems including, but not limited to, methods, apparatuses, structures, devices, and systems for dissipating heat generated at a server system.

### BACKGROUND

During operation, a server rack generates significant heat, which can lead to thermal management challenges within the confined space of the server rack. Overheating at the server rack can result in reduced performance or even hardware failure if not properly managed with adequate cooling solutions. Conventional heat dissipation solutions rely on a coolant system that occupies at least a space, in the server rack, which otherwise could be occupied by computational hardware, thereby compromising computational hardware density within the server rack. Under some circumstances, due to a spatial limitation, the conventional coolant system can only dissipate limited amount of heat generated by the computational hardware accommodated by the server rack, and requires cooling structures to be installed in multiple rack units within a single server rack. Therefore, a need exists for an improved systems, methods, and devices that addresses one or more of the above-described disadvantages, in a manner that is cost-effective, efficient, reliable, and scalable.

### SUMMARY

Various embodiments of this application are directed to methods, apparatuses, structures, devices, and systems for dissipating heat generated by server systems.

In some embodiments, the present disclosure is directed to providing a rack structure that dissipates heat at a server system. In some embodiments, the server system includes a coolant distribution unit (CDU), which is configured to circulate liquid for transferring heat generated by the server system to the liquid. In some embodiments, the rack structure of the present disclosure includes one or more inlets and/or one or more outlets disposed at a front edge portion of the rack structure, such as due to spatial design limitations associated with the server system. In some embodiments, the rack structure include one or more coolant distribution manifolds that is configured to receive and circulate the liquid, such as a coolant, from the server system and the CDU. In some embodiments, the rack structure is configured to utilize an edge portion, such as a front edge between two or more mounting rails and two or more side panels of the rack structure, which allows for routing fluid through one or more coolant distribution manifolds of the CDU.

Turning to more specific aspects, one aspect of the present disclosure is directed to providing a server rack. In some embodiments, the server rack includes a rack structure. The rack structure includes a plurality of slots for receiving at least one rack servers. Moreover, the server rack includes a first coolant distribution manifold and a second coolant distribution manifold. The first coolant distribution manifold is coupled to a first front edge of the rack structure, in which the first front edge extends adjacent to the plurality of slots. Furthermore, the first coolant distribution manifold includes a plurality of outlets that is configured to provide coolant flows to the one or more rack servers from the first front edge of the rack structure. The second coolant distribution manifold is coupled to a second front edge of the rack structure, in which the second front edge extends adjacent to the plurality of slots. Additionally, the second coolant distribution manifold includes a plurality of inlets that is configured to collect, from the second front edge of the rack structure, the coolant flows exiting the one or more rack servers.

In some embodiments, the rack structure is disposed on a supporting surface, and the first coolant distribution manifold and the second coolant distribution manifold extend in parallel with a direction that is substantially perpendicular to the supporting surface.

In some embodiments, the first front edge opposes the second front edge, and the plurality of slots is located between the first front edge and the second front edge of the rack structure.

In some embodiments, the first front edge is the second front edge, and the first coolant distribution manifold and the second coolant distribution manifold are disposed closely to one another on the same first front edge of the rack structure.

In some embodiments, the server rack includes a third coolant distribution manifold coupled to an opposite front edge, of the rack structure, distinct from the first front edge, and the third coolant distribution manifold is configured to provide supplemental coolant flows to the one or more rack servers.

In some embodiments, the server rack includes a fourth coolant distribution manifold coupled to an opposite front edge, of the rack structure, distinct from the first front edge, and the fourth coolant distribution manifold is configured to collect respective coolant flows from the one or more rack servers.

In some embodiments, the plurality of outlets is distributed substantially evenly on at least a portion of the first coolant distribution manifold, and the plurality of inlets is distributed substantially evenly on at least a portion of the second coolant distribution manifold.

In some embodiments, the server rack further includes a plurality of rack servers disposed in parallel between the first front edge and the second front edge of the rack structure, each rack server being received by a respective subset of the plurality of slots.

In some embodiments, at least two of the plurality of rack servers is disposed on two immediately adjacent slots of the rack structure, and include a first rack server and a second rack server. A bottom surface of the first rack server and a top surface of the second rack server has a distance that is smaller than a separation threshold.

In some embodiments, the plurality of rack servers include a first rack server, and the first rack server includes a cooling structure coupled to a subset of inlets of the second coolant distribution manifold and a subset of outlets of the first coolant distribution manifold. Moreover, the cooling structure is configured to dissipate heat generated by the first rack server by receiving a first coolant flow from the first coolant distribution manifold, circulating the first coolant flow through part of the first rack server, and outputting the first coolant flow to the second coolant distribution manifold.

In some embodiments, the plurality of rack servers include a plurality of graphics processing units (GPU) configured to implement machine learning operations.

In some embodiments, the server rack further includes a coolant distribution unit (CDU) disposed in one of the plurality of slots of the rack structure, in which the CDU is coupled to the first coolant distribution manifold and the second coolant distribution manifold via two coolant tubes, and configured to provide and collect the coolant flows via the two coolant tubes. Moreover, the CDU has a front surface facing forward and disposed in proximity to the first front edge and the second front edge of the rack structure.

In some embodiments, the CDU further includes a rear surface that opposes the front surface of the CDU, and the rear surface of the CDU further includes a coolant source interface configured to exchange a central coolant flow with an external coolant source (e.g., source 380 in FIG. 3B).

In some embodiments, the CDU further includes a rear surface that opposes the front surface of the CDU, and the rear surface of the CDU further includes a tube interface configured to provide the coolant flows to the first coolant distribution manifold and collect the coolant flows from the second coolant distribution manifold.

In some embodiments, the two coolant tubes are coupled to the tube interface and disposed within the one of the plurality of slots of the rack structure to extend to the front surface to access the first coolant distribution manifold and the second coolant distribution manifold.

In some embodiments, the CDU further includes a rear surface that opposes the front surface of the CDU. Moreover, the rear surface of the CDU further includes a first tube interface coupled to one of the first coolant distribution manifold and the second coolant distribution manifold. Furthermore, the front surface of the CDU further includes a second tube interface coupled to the other one of the first coolant distribution manifold and the second coolant distribution manifold.

In some embodiments, the front surface of the CDU further includes a tube interface configured to provide the coolant flows to the first coolant distribution manifold and collect the coolant flows from the second coolant distribution manifold.

In some embodiments, the CDU further includes a coolant pump and a coolant controller coupled to the coolant pump. The coolant controller is configured to control the coolant pump to push a central coolant into the first coolant distribution manifold and collect the central coolant from the second coolant distribution manifold.

In some embodiments, the server rack includes, or is coupled to, a plurality of panels configured to convert the server rack to a server cabinet.

Another aspect of the present disclosure is directed to providing a server system. The server system includes a plurality of rack servers and a rack structure for supporting the plurality of rack servers. Moreover, the server system includes a first coolant distribution manifold and a second coolant distribution manifold. The first coolant distribution manifold is coupled to a first front edge of the rack structure, the first front edge extending adjacent to the plurality of rack servers. The first coolant distribution manifold includes a plurality of outlets that are configured to provide coolant flows to the plurality of rack servers from the first front edge of the rack structure. Moreover, the second coolant distribution manifold is coupled to a second front edge of the rack structure, the second front edge extending adjacent to the plurality of rack servers. The second coolant distribution manifold includes a plurality of inlets that are configured to collect, from the second front edge of the rack structure, the coolant flows exiting the plurality of rack servers.

Yet another aspect of the present disclosure is directed to providing a method for controlling heat dissipation in a server system. The method includes providing a rack structure to support a plurality of rack servers. The method further includes providing a first coolant distribution manifold coupled to a first front edge of the rack structure, the first front edge extending adjacent to the plurality of rack servers. The first coolant distribution manifold includes a plurality of outlets that are configured to provide coolant flows to the plurality of rack servers from the first front edge of the rack structure. Additionally, the method includes providing a second coolant distribution manifold coupled to a second front edge of the rack structure, the second front edge extending adjacent to the plurality of rack servers. The second coolant distribution manifold includes a plurality of inlets that are configured to collect, from the second front edge of the rack structure, the coolant flows exiting the plurality of rack servers.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a front view of an example server rack that supports one or more servers, in accordance with some embodiments.

FIG. 2 is a block diagram of an example system module in a typical computer device, which may be applied as a server in FIG. 1, in accordance with some embodiments.

FIG. 3A is a perspective view of an example server rack including a cool distribution unit (CDU), in accordance with some embodiments.

FIGS. 3B-3E illustrates another four example CDUs for exchanging coolant with an external coolant source, in accordance with some embodiments.

FIG. 4A is a front view of an example server rack including a server cooling system, in accordance with some embodiments, and FIG. 4B is a rear view of the example server rack shown in FIG. 4A, in accordance with some embodiments.

FIGS. 5 and 6 are front views of another two example server racks each of which supports one or more servers, in accordance with some embodiments.

FIG. 7 is a schematic view of a cooling structure applied by a rack server, in accordance with some embodiments.

FIG. 8 is a schematic diagram comparing a first server rack including front coolant manifolds to a second server rack, in accordance with some embodiments.

FIG. 9 is a flow diagram of a method for providing a server rack, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details.

FIG. 1 is a front view of an example server rack 100 (also known as a rack mount, a rack cabinet, or simply a rack) that supports one or more rack servers 120, in accordance with some embodiments. The server rack 100 includes a rack structure 102 (also known as a frame) and a plurality of slots 104 (also known as rack units (RUs), and may be used in a data center, a server room, or a network closet for supporting, organizing, and managing a plurality of computing equipment modules 106 (e.g., rack servers 120, storage devices 116S and 116N, networking equipment, and other types of hardware). Each of the plurality of slots 104 of the server rack 100 is configured to receive and support a respective computing equipment module 106. In some embodiments, the plurality of slots 104 includes at least one blank slot 104B that is not used to provide mechanical support to any equipment module 106 and can receive an equipment module 106 if needed.

In some embodiments, the server rack 100 further includes a plurality of rack servers 120, such as at least 4 rack servers 120, at least 6 rack servers 120, at least 8 rack servers 120, at least 10 rack servers 120, at least 20 rack servers 120, or the like. In some embodiments, the server rack 100 further includes at most 4 rack servers 120, at most 6 rack servers 120, at most 8 rack servers 120, at most 10 rack servers 120, at most 20 rack servers 120, or the like. In some embodiments, the plurality of rack servers 120 is disposed in parallel between a first front edge 140-1 and a second front edge 140-2 of the rack structure 102. Accordingly, in some embodiments, each rack server 120 in the plurality of rack servers 120 is configured to be received by a respective slot 104 in the plurality of slots 104.

In some embodiments, at least two of the plurality of rack servers 120 is disposed on two immediately adjacent slots 104 in the plurality of slots 104 of the rack structure 102, such that a first rack server 120-1 is disposed adjacent to a second rack server 120-2 in the plurality of rack servers 120. For instance, in some embodiments, a bottom surface of the first rack server and a top surface of the second rack server has a distance that is smaller than a separation threshold. In some embodiments, the server rack 100 has a predefined width of 19 or 23 inches, a height up to 84 inches or more, and a depth selected from 24, 32, 40, or 48 inches. However, the present disclosure is not limited thereto.

Examples of the computing equipment modules 106 supported by the plurality of slots 104 of the server rack 100 include, but are not limited to, a firewall module 108, a switch box 110, a rack server 120, a display device 112, a keyboard 114, a solid-state drive (SSD) 116S, a network-attached storage 116N, and an uninterruptible power supply (UPS) 118. Each computing equipment module 106 plays a respective role in maintaining a network and computing environment. In some embodiments, a firewall module 108 is a network security device that monitors and controls incoming and outgoing network traffic based on predetermined security rules, thereby establishing a barrier between a trusted internal network and untrusted external networks. The firewall module 108 may be placed near a network ingress point to protect the server rack 100 from unauthorized access, malware, and cyberattacks. In some embodiments, the firewall module 108 includes packet filtering, stateful inspection, VPN support, and intrusion prevention systems (IPS). In some embodiments, a switch box 110 is placed near the network ingress point jointly with the firewall module 108, and configured to receive incoming signals and forward the incoming signals (e.g., which may be converted to electrical signals) to different rack servers 120 mounted on the server rack 100. The switch box 110 is applied in the server rack 100 to minimize cable length and ensure efficient network traffic management. The switch box 110 may support different speeds (e.g., 800 gigabits per second (Gbps), 1.6 Tbs, 3.2 Tbs), have multiple ports (24, 48, etc.), and offer features like virtual local area network (VLAN) support, PoE (Power over Ethernet), and managed or unmanaged capabilities.

The plurality of computing equipment modules 106 of the server rack 100 may include a plurality of rack servers 120 each of which is configured to provides data, resources, services, or programs to other client devices over one or more wired or wireless communication networks. Each rack server 120 is mounted in a slot 104 of the server rack 100 and configured to provide one or more services (e.g., web hosting, database management, and application support). The rack servers 120, mounted on the server rack 100, may provide higher processing power, large memory capacity, redundant power supplies, and hot-swappable components for high availability and reliability compared with individual client devices. In some embodiments, the one or more rack servers 120 include a plurality of graphics processing units (GPU) configured to implement machine learning operations, e.g., in a data center associated with machine learning tasks.

The SSD 116S and the network-attached storage 116N are configured to provide storage space for the rack servers 120 installed in the server rack 100. The SSD uses flash memory to store data and shows high speed, low latency, durability, and lower power consumption, and diverse capacities and form factors compared to hard drive devices (HDDs). Conversely, the network-attached storage (NAS) 116N is a dedicated file storage device that provides data access to a network and allows a large number of different types of client devices to retrieve data from centralized disk capacity. In some embodiments, the network-attached storage 116N may have a high capacity, redundant array of independent disks (RAID), support for a plurality of file-sharing protocols (NFS, SMB/CIFS, FTP), user management, and backup features. In some embodiments, the SSDs 116S are storage drives for speed, and for example, used within the rack servers 120 disposed on the same server rack 100, while the NAS 116N is configured for file sharing, data backup, and remote access.

In some implementations, the UPS 118 is applied to provide emergency power to other computing equipment modules 106 in case of a power outage, allowing them to remain operational long enough to safely shut down or switch to an alternative power source. In an example, the UPS 118 is mounted in the server rack 100 or placed on a bottom slot to support the weight, providing backup power to other computing equipment modules 106. The UPS 118 provides one or more of battery backup, surge protection, voltage regulation, real-time monitoring, management software, and/or varying runtimes based on capacity and load.

The server rack 100 further includes a plurality of mechanical structures configured to provide mechanical support, or facilitate access, to the plurality of computing equipment modules 106. The plurality of mechanical structures include one or more of: an open frame rack (e.g., having no door or side panel), mounting rails, cable management features (e.g., arms, hooks, and trays), power strips, shelves, drawers, and blanking panels. In some embodiments, the plurality of mechanical structures also includes a rack enclosure (e.g. cabinet), lockable doors, and side panels to protect the computing equipment modules 106 from unauthorized access. In an example, the server rack 100 includes, or is coupled to, a plurality of panels configured to convert the server rack 100 to a server cabinet. In some embodiments, the server rack 100 further includes a cooling system or a ventilation system to facilitate heat dissipation. Using a server rack 100 helps optimize space, improve cooling efficiency, simplify maintenance, and enhance the overall organization and management of information technology (IT) infrastructure.

Some implementations of the server rack 100 include a rack structure 102 (e.g., including a frame and a plurality of slots 104) for supporting one or more rack servers 120. In some implementations, the rack structure 102 fully encloses the one or more rack servers 120 and a cooling distribution unit (CDU). The one or more rack servers 120 is mechanically mounted on the rack structure 102.

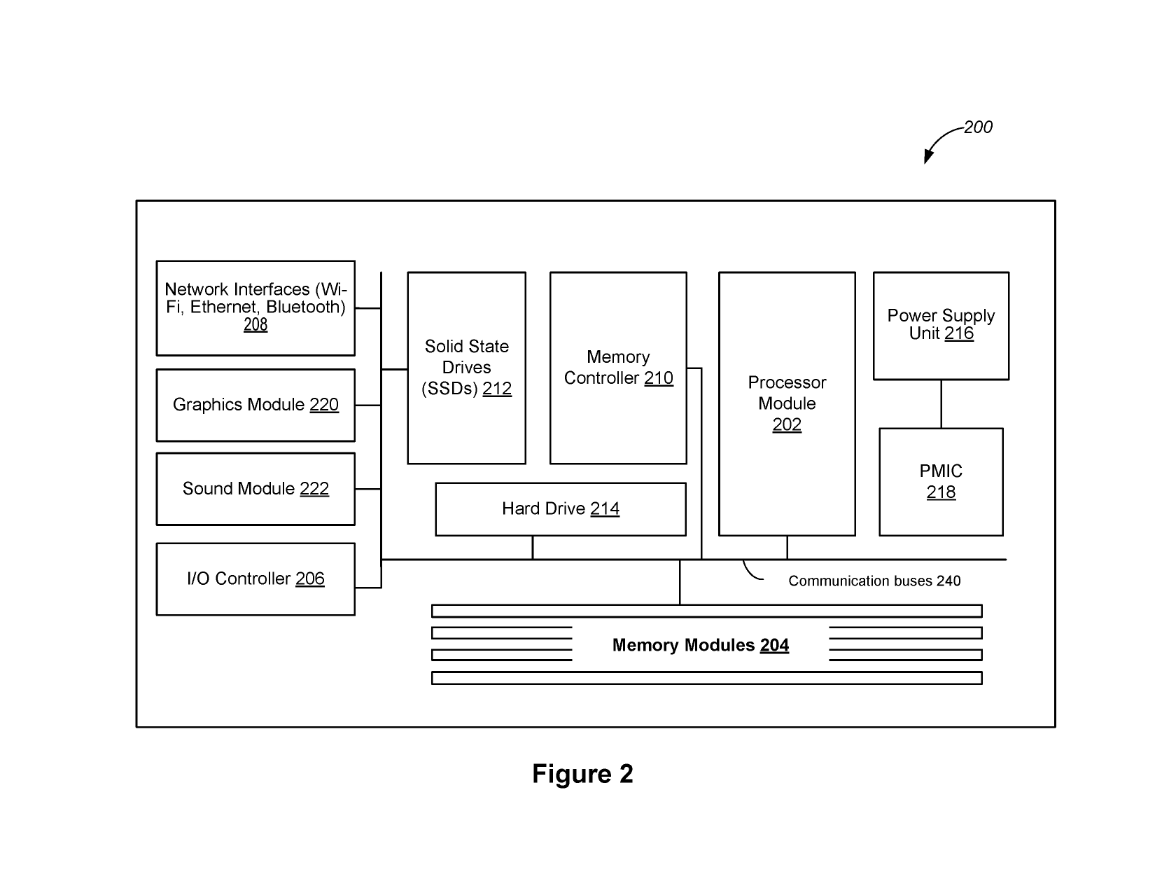

FIG. 2 is a block diagram of an example system module 200 (e.g., a GPU server) in a typical computer device, which may be applied as a rack server 120 in FIG. 1, in accordance with some embodiments. The system module 200 in this computer device includes at least a processor module 202, memory modules 204 for storing programs, instructions and data, an input/output (I/O) controller 206, one or more communication interfaces such as network interfaces 208, and one or more communication buses 240 for interconnecting these components. In some embodiments, the I/O controller 206 allows the processor module 202 to communicate with an I/O device (e.g., a keyboard, a mouse or a track-pad) via a universal serial bus interface. In some embodiments, the network interfaces 208 includes one or more interfaces for Wi-Fi, Ethernet and Bluetooth networks, each allowing the computer device to exchange data with an external source, e.g., a server or another computer device. In some embodiments, the communication buses 240 include circuitry (sometimes called a chipset) that interconnects and controls communications among various system components included in system module 200.

In some embodiments, the memory modules 204 include high-speed random-access memory, such as DRAM, static random-access memory (SRAM), double data rate (DDR) dynamic random-access memory (RAM), or other random-access solid state memory devices. In some embodiments, the memory modules 204 include non-volatile memory, such as one or more magnetic disk storage devices, optical disk storage devices, flash memory devices, or other non-volatile solid state storage devices. In some embodiments, the memory modules 204, or alternatively the non-volatile memory device(s) within the memory modules 204, include a non-transitory computer readable storage medium. In some embodiments, memory slots are reserved on the system module 200 for receiving the memory modules 204. Once inserted into the memory slots, the memory modules 204 are integrated into the system module 200.

In some embodiments, the system module 200 further includes one or more components selected from a memory controller 210, solid state drives (SSDs) 212, a hard disk drive (HDD) 214, a power supply unit (PSU) 216, power management integrated circuit (PMIC) 218, a graphics module 220, and a sound module 222. The memory controller 210 is configured to control communication between the processor module 202 and memory components, including the memory modules 204, in the computer device. The SSDs 212 are configured to apply integrated circuit assemblies to store data in the computer device, and in many embodiments, are based on NAND or NOR memory configurations. The HDD 214 is a conventional data storage device used for storing and retrieving digital information based on electromechanical magnetic disks. The PSU 216 is configured to receive an external power supply and provide a plurality of DC power supplies (e.g., 12V, 54V). The PMIC 218 is configured to modulate the plurality of DC power supplies to other desired DC voltage levels, e.g., 5V, 3.3V or 1.8V, as required by various components or circuits (e.g., the processor module 202) within the computer device. The graphics module 220 is configured to generate a feed of output images to one or more display devices according to their desirable image/video formats. The sound module 222 is configured to facilitate the input and output of audio signals to and from the computer device under control of computer programs.

It is noted that communication buses 240 also interconnect and control communications among various system components including components 210-222.

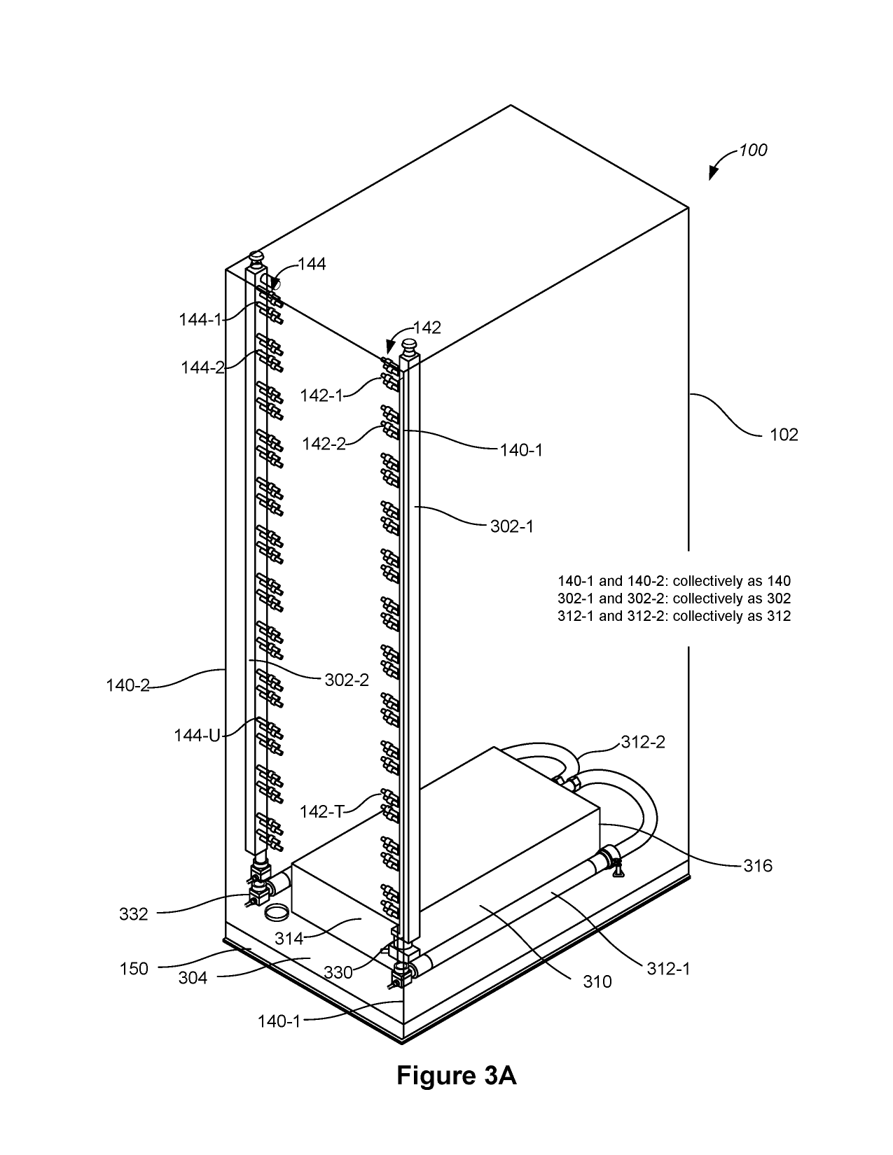

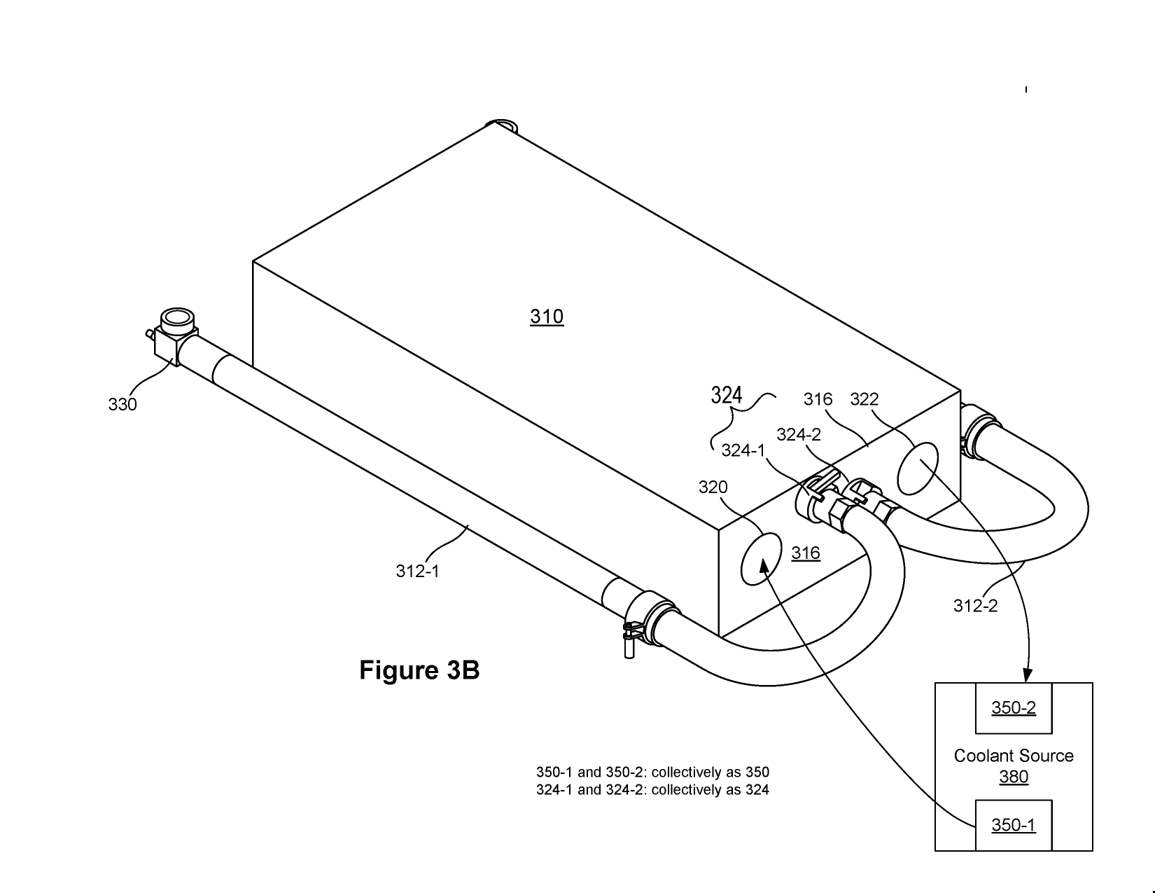

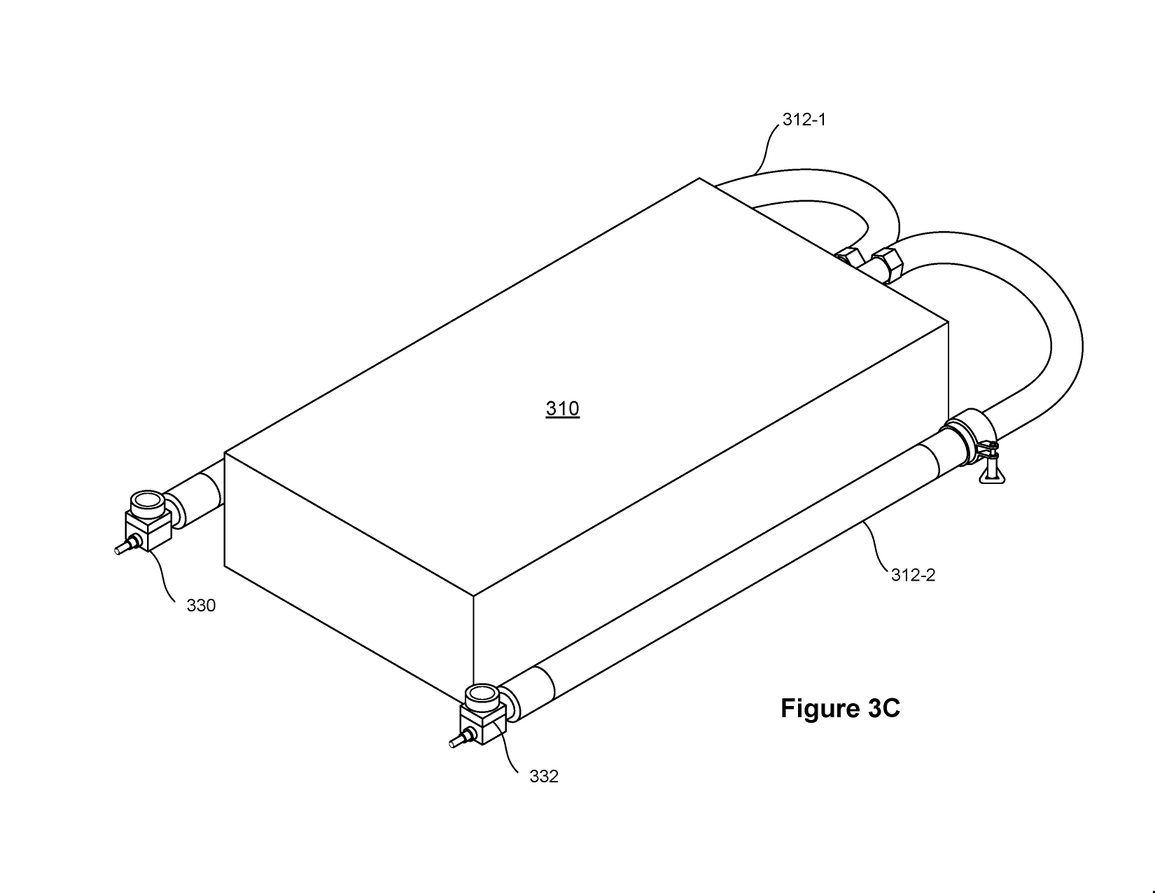

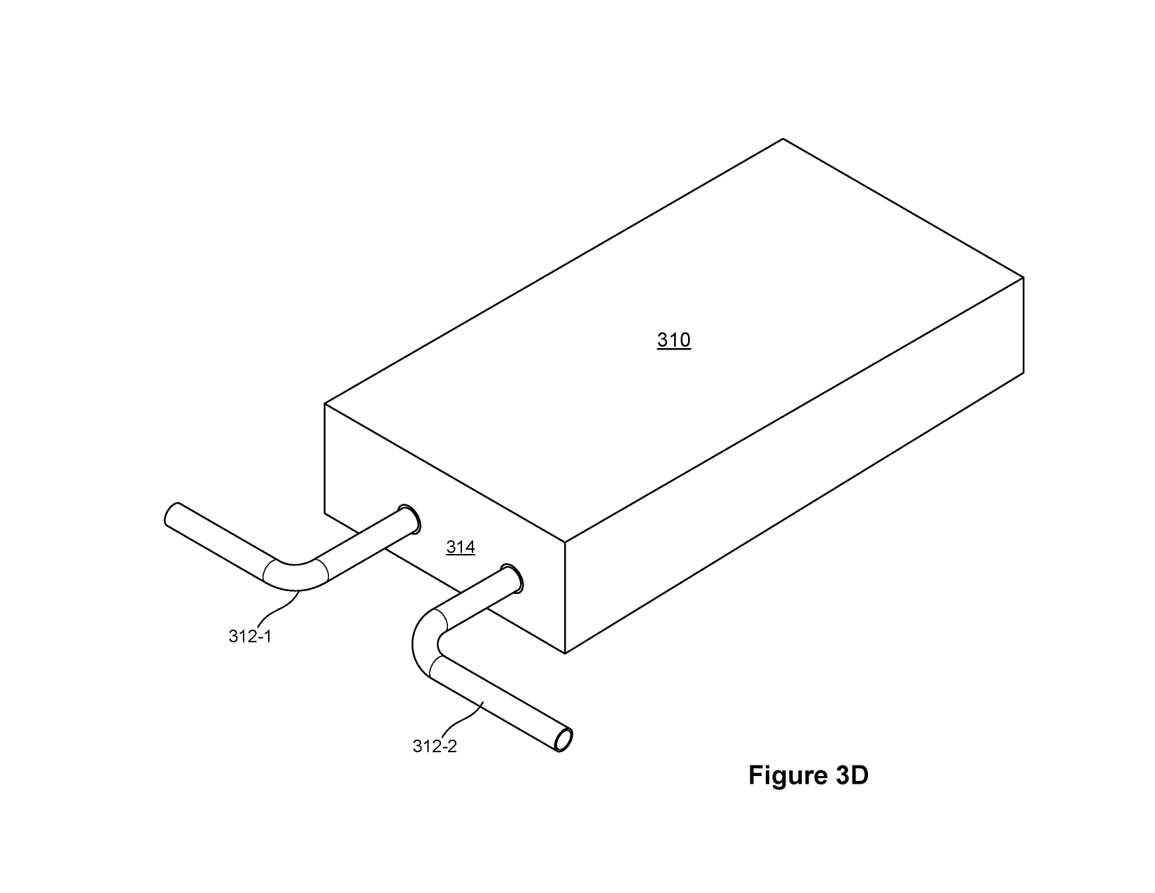

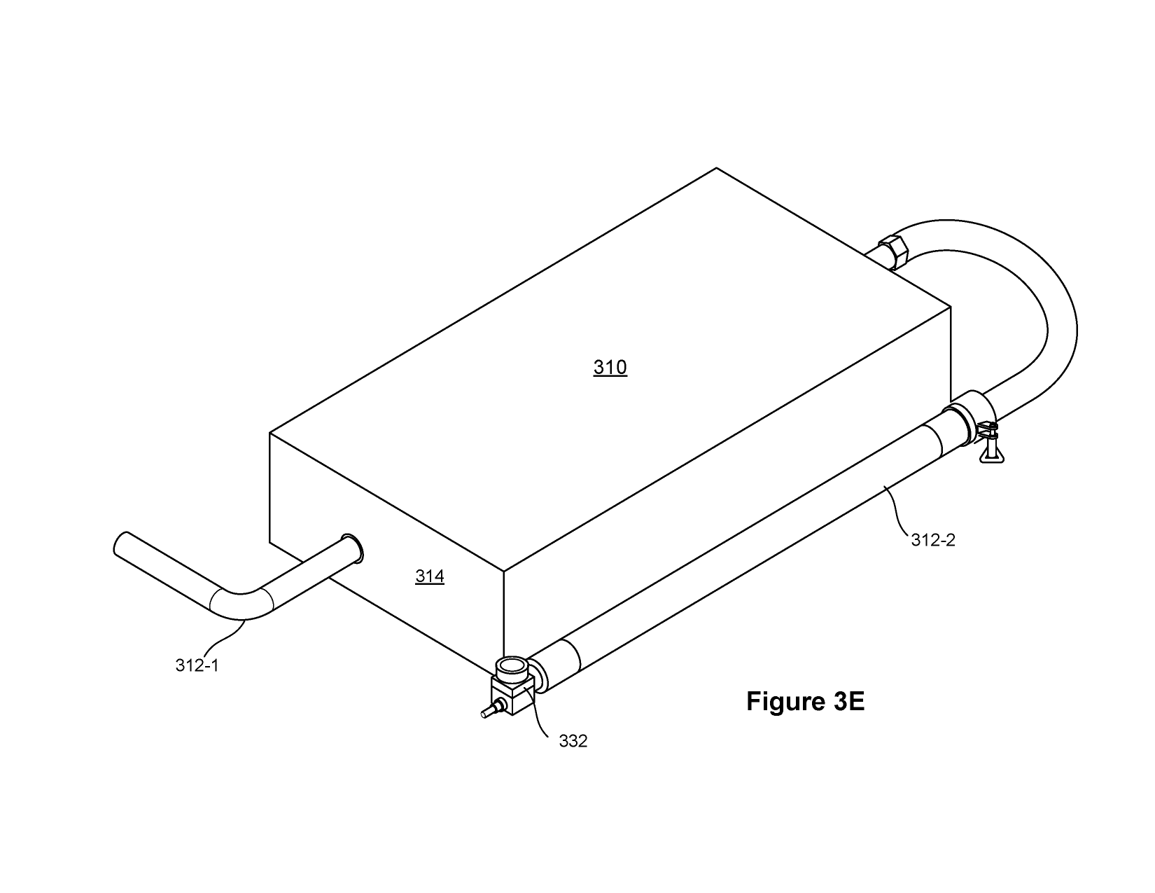

FIG. 3A is a perspective view of an example server rack including a cool distribution unit (CDU), in accordance with some embodiments. FIGS. 3B-3E illustrates another four example CDUs 310 for exchanging coolant with an external coolant source 380, in accordance with some embodiments. Referring to FIG. 3A, in some embodiments, the rack structure 102 of the server rack 100 is disposed on a supporting surface 304 of the server rack 100, such as an upper surface of a base 150 that is configured to accommodate the rack structure 102. In some embodiments, the rack structure 102 is fixed disposed on the supporting surface 304. However, the present disclosure is not limited thereto.

Furthermore, in some embodiments, the server rack 100 includes one or more coolant distribution manifolds 302, such as a first coolant distribution manifold 302-1 and a second coolant distribution manifold 302-2. In some embodiments, the server rack 100 includes at least two coolant distribution manifolds 302, which allows for using the first coolant distribution manifold 302-1 to circulate cool coolant through some or all of the server rack 100 and receive warm coolant that is heated by some or all of the plurality of computing equipment modules 106 via the second coolant distribution manifold 302-2. However, the present disclosure is not limited thereto. In some embodiments, the server rack 100 includes at least three coolant distribution manifolds 302, at least four coolant distribution manifolds 302, or at least five coolant distribution manifolds 302. In some embodiments, the server rack 100 includes at most two coolant distribution manifolds 302, at most three coolant distribution manifolds 302, at most four coolant distribution manifolds 302, or at most five coolant distribution manifolds 302. In some embodiments, the server rack 100 includes between one and six coolant distribution manifolds 302, between one and four coolant distribution manifolds 302, between one and two coolant distribution manifolds 302, between two and six coolant distribution manifolds 302, between two and four coolant distribution manifolds 302, or between four and six coolant distribution manifolds 302. Accordingly, in some embodiments, the server rack 100 is configured to circulate coolant flow through some or all of the rack structure 102 using one coolant distribution manifold 302 in the plurality of distribution manifolds 302 (e.g., a first coolant distribution manifold 302-1 and a second coolant distribution manifold 302-2). The coolant flow may flow through some or all of the rack structure 102, thereby colling and dissipating heat generated by computing equipment modules 106 (e.g., servers 120) of the server rack 100. However, the present disclosure is not limited thereto. by a plurality of coolant distribution manifolds 302.

In some embodiments, each respective coolant distribution manifold 302 of the server rack 100 is coupled to the rack structure 102 at a corresponding front edge or front edge portion 140 of the rack structure 102. For instance, in some embodiments, the first coolant distribution manifold 302-1 is coupled to a first front edge 140-1 of the rack structure and the second coolant distribution manifold 302-2 is coupled to a second front edge 140-2 of the rack structure 102, in which the first front edge 140-1 is different from the second front edge 140-2 of the rack structure. However, the present disclosure is not limited thereto. In some embodiments, the front edge of the rack structure is an interior edge portion of the rack structure 102, which allows for housing the respective coolant distribution manifold 302 within an interior of the rack structure 102. In some embodiments, the front edge 140 of the rack structure 102 is an exterior surface or an exposed surface of the rack structure 102, which allows for easy accessibility to the respective coolant distribution manifold 302, such as for maintenance thereof. Accordingly, in some embodiments, by coupling each coolant distribution manifold 302 in the one or more coolant distribution manifolds 302 to a different front edge or front edge portion 140 of the rack structure 102, the first coolant distribution manifold 302-1 is physically separated from the second coolant distribution manifold 302-2, limiting indirect heat transfer between the first coolant distribution manifold 302-1 and the second coolant distribution manifold 302-2. For instance, in some embodiments, the first front edge 140-1 of the rack structure 102 opposes the second front edge 140-2 of the rack structure 102, such that the plurality of slots 104 is located between the first front edge 140-1 and the second front edge 140-2 of the rack structure 102.

In some embodiments, the second coolant distribution manifold 302-2 is coupled to the second front edge 140-2 of the rack structure 102. In some embodiments, the second front edge 140-2 extends adjacent to the plurality of slots 104. For instance, in some embodiments, the plurality of slots 104 and the second front edge 140-2 of the rack structure 102 extend along a longitudinal axis of the rack structure 102, which places the plurality of slots 104 is close proximity to the second front edge 140-2 of the rack structure 102.

Furthermore, the first coolant distribution manifold 302-1 includes a plurality of outlets 142 (e.g., outlets 142-1, 142-2, …, 142-T in FIG. 3A). In some embodiments, the plurality of outlets 142 is configured to provide coolant flows to the one or more rack servers 120. For instance, in some embodiments, the plurality of outlets 142 provide coolant flow from the first front edge of the rack structure 102 to the one or more rack servers 120.

Additionally, the second coolant distribution manifold 302-2 includes a plurality of inlets 144 (e.g., 144-1, 144-2, …, 144-U in FIG. 3A). In some embodiments, the plurality of inlets 144 is configured to collect the coolant flows exiting the one or more rack servers 120. For instance, in some embodiments, the plurality of inlets 144 collect the coolant flow exiting the one or more rack servers 120 from the second front edge 140-2 of the rack structure 102. As a non-limiting example, in some embodiments, the plurality of outlets 142 provide coolant (e.g., cool fluid) flow from the first front edge of the rack structure 102 to the one or more rack servers 120 and the plurality of inlets 144 collect the coolant flow exiting the one or more rack servers 120 from the second front edge 140-2 of the rack structure 102 after the coolant flow is heated by the one or more rack servers 120.

In some embodiments, the first coolant distribution manifold 302-1 and the second coolant distribution manifold 302-2 extend in parallel, or substantially in parallel, with a direction that is perpendicular, or substantially perpendicular, to the supporting surface 304. For instance, in some embodiments, the supporting surface 304 is level or horizontal with respect to the ground, such that the first coolant distribution manifold 302-1 and the second coolant distribution manifold 302-2 extend vertically in parallel, or substantially in parallel, perpendicular to the ground.

In some embodiments, the first front edge 140-1 is the second front edge 140-2, such that the first coolant distribution manifold 302-1 and the second coolant distribution manifold 302-2 are disposed closely to one another on the same first front edge 140 of the rack structure 102.

Referring to FIGS. 3B-3E, in some embodiments, the server rack 100 further includes a coolant distribution unit (CDU) 310. In some embodiments, the CDU 310 is disposed in a slot 104 of the plurality of slots 104 of the rack structure 102. The CDU 310 is coupled to the first coolant manifold 302-1 and the second coolant manifold 302-2 via a first coolant tube 312-1 and a second coolant tube 312-2, respectively. Referring to FIGS. 3B and 3C, in some embodiments, both of the first coolant tube 312-1 and the second coolant tube 312-2 are coupled to a rear surface 316 of the CDU 310, routed adjacently to the CDU 310 to the front edges 140-1 and 140-2, and coupled to the coolant manifolds 302-1 and 302-2 near the front edges 140-1 and 140-2. Referring to FIG. 3D, in some embodiments, both of the first coolant tube 312-1 and the second coolant tube 312-21 are coupled to a front surface 314 of the CDU 310, routed in front of the CDU 310, and coupled to the coolant manifolds 302-1 and 302-2 near the front edges 140-1 and 140-2. Referring to FIG. 3E, in some embodiments, the first coolant tube 312-1 is coupled to the front surface 314, routed in front of the CDU 310, and coupled to the first coolant manifolds 302-1. The second coolant tube 312-2 is coupled to the rear surface 316 the CDU 310, routed adjacently to the CDU 310 to the front edge 140-2, and coupled to the second coolant manifolds 302-2. In some embodiments not shown, the first coolant tube 312-1 is coupled to the rear surface 316, while the second coolant tube 312-2 is coupled to the front surface 314 of the CDU 310.

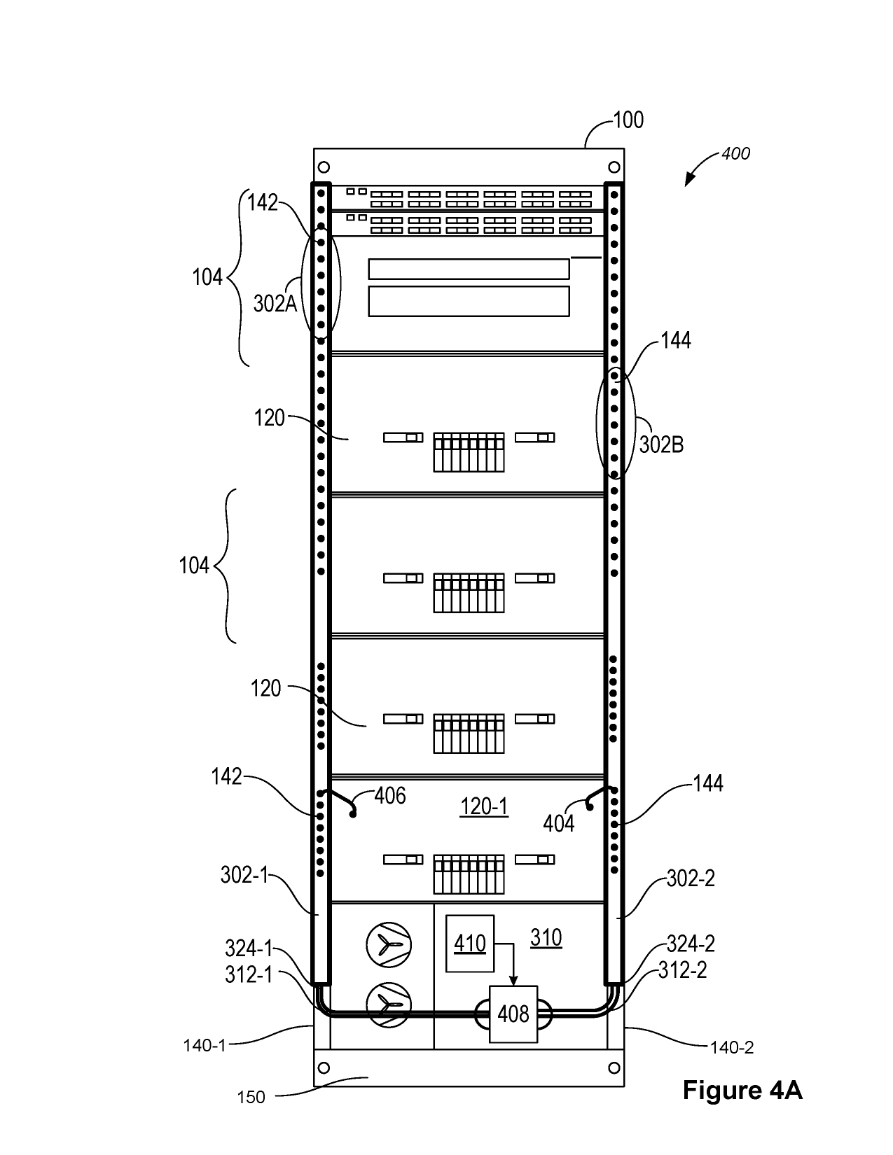

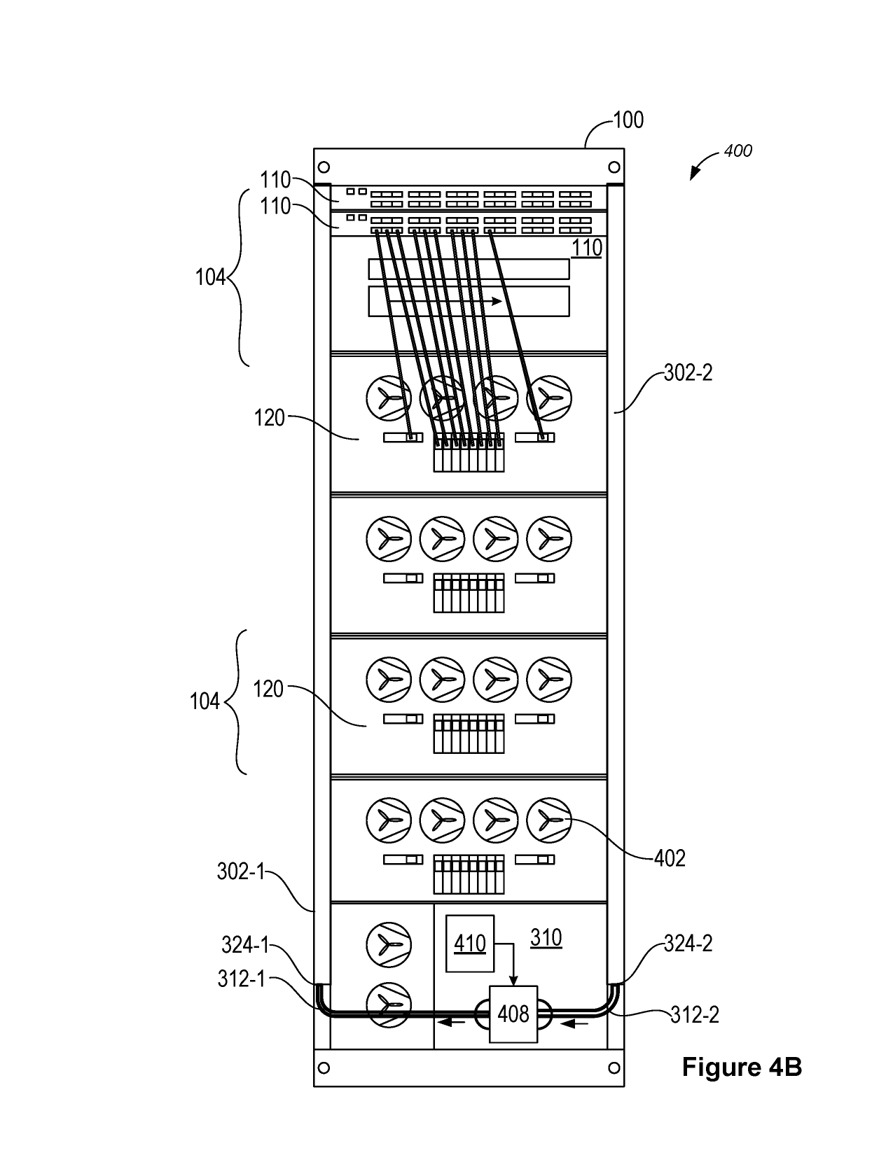

FIG. 4A is a front view of an example server rack 100 including a server cooling system 400, in accordance with some embodiments, and FIG. 4B is a rear view of the example server rack 100 shown in FIG. 4A, in accordance with some embodiments. The server cooling system 400 relies on liquid cooling. In some embodiments, the server rack 100 including the server cooling system 400 is applied in a data center applied to implement machine learning tasks (e.g., training deep neural networks, executing large language models (LLM)). The server rack 100 includes a plurality of slots 104 for receiving and supporting a respective computing equipment module 106 (e.g., a GPU server 120).

The server rack 100 includes a rack structure including a plurality of slots 104 for receiving at least one or more rack servers 120 or other equipment module 106. Referring to FIG. 4A, the server rack 100 includes a first coolant distribution manifold 302-1 coupled to a first front edge 140-1 of the rack structure that extends adjacent to the plurality of slots 104. The first coolant distribution manifold 302-1 includes a plurality of outlets 142 configured to provide coolant flows to the one or more rack servers 120 from the first front edge 140-1 of the rack structure. The server rack 100 further includes a second coolant distribution manifold 302-2 coupled to a second front edge 140-2 of the rack structure that extends adjacent to the plurality of slots. The second coolant distribution manifold 302-2 includes a plurality of inlets 144 configured to collect, from the second front edge 140-2 of the rack structure, the coolant flows exiting the one or more rack servers 120. For example, one of the plurality of outlets 142 is coupled to a coolant inlet of a first server 120-1 via a tube 406, and one of the plurality of inlets 144 is coupled to a coolant outlet of the first server 120-1 via a tube 404.

In some embodiments, referring to FIG. 4A, a coolant pump 408 is coupled between the two tubes 312-1 and 312-2, which are further coupled to the coolant distribution manifold 302-1 and 302-2. A coolant controller 410 is coupled to the coolant pump 408, and configured to control the coolant pump 408 to push the coolant into one of the two tubes 312 and draw the coolant back from the other one of the two tubes 312. Further, in some embodiments, the coolant pump 408 is disposed in a bottommost tray of the server rack 100. In some embodiments, referring to FIG. 4B, each GPU server 120 or the CDU includes one or more respective fans 402 within an associated free slot space, and each respective fans 402 is configured to enhance circulation of air and increase heat dissipation via air convection in the respective slot 104 where the GPU server 120 is disposed.

In some embodiments, the plurality of outlets 142 is distributed substantially evenly on at least a portion 302A of the first coolant distribution manifold 302-1, and the plurality of inlets 144 is distributed substantially evenly on at least a portion 302B of the second coolant distribution manifold 302-2.

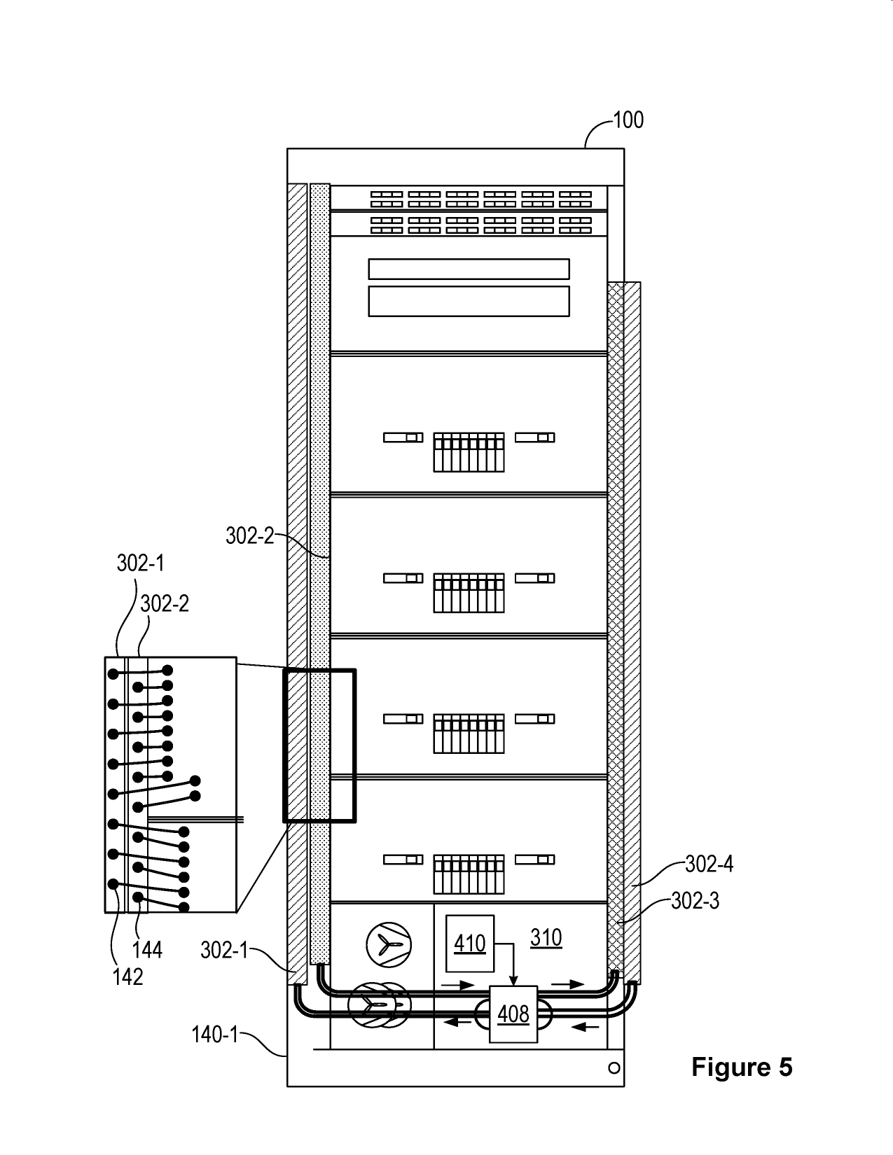

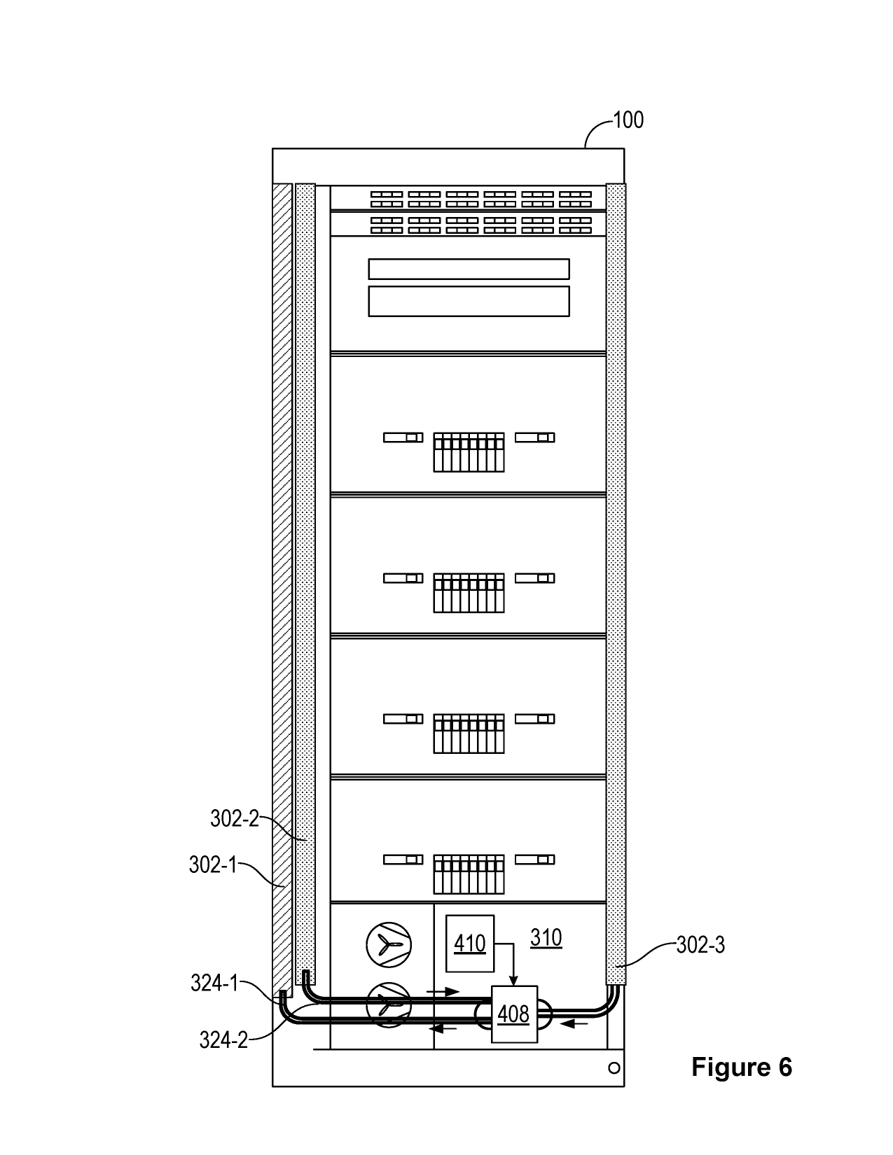

FIGS. 5 and 6 are front views of another two example server rack 100 each of which supports one or more servers 120, in accordance with some embodiments. In some embodiments, the first coolant distribution manifold 302-1 and the second coolant distribution manifold 302-2 are disposed closely to one another on the same first front edge 140-1 of the rack structure. The server rack 100 further includes a third coolant distribution manifold 302-3. In some embodiments, the third coolant distribution manifold 302-3 is coupled to an opposite front edge of the rack structure 102 that is distinct from the first front edge 140-1 of the rack structure 102.

In some embodiments, the third coolant distribution manifold 302-3 is configured to provide supplemental coolant flows to the one or more rack servers 120. For instance, in some embodiments, the third coolant distribution manifold 302-3 is configured to provide coolant flow to a first rack server 120-1 of the at least one rack servers 120 and the first coolant distribution manifold 302-1 is configured to provide coolant flow to a second rack server 120-2 of the rack structure 102. As a non-limiting example, in some embodiments, the first coolant distribution manifold 302-1 is configured to provide coolant flow to one or more rack servers 120 at an upper end portion of the rack structure 102 and the third coolant distribution manifold 302-3 is configured to provide coolant flow to one or more rack servers 120 at a lower end portion of the rack structure 102, such as to reduce a threshold pressure needed to provide the coolant to the upper end portion of the rack structure 102, such as a head loss or minor loss of pressure. However, the present disclosure is not limited thereto.

In some embodiments, the server rack 100 includes a fourth coolant distribution manifold 302-4. In some embodiments, the fourth coolant distribution manifold 302-4 is coupled to an opposite front edge, of the rack structure, distinct from the first front edge 140-1. In some embodiments, the fourth coolant distribution manifold 302-4 is configured to collect respective coolant flows from the one or more rack servers 120. For instance, the fourth coolant distribution manifold includes a plurality of inlets 144 collect the coolant flow exiting the one or more rack servers 120 from the second front edge 140-2 of the rack structure 102. As a non-limiting example, in some embodiments, the plurality of outlets 142 provide coolant (e.g., cool fluid) flow from the first front edge of the rack structure 102 to the one or more rack servers 120 and the plurality of inlets 144 collect the coolant flow exiting the one or more rack servers 120 from the second front edge 140-2 of the rack structure 102 after the coolant flow is heated by the one or more rack servers 120.

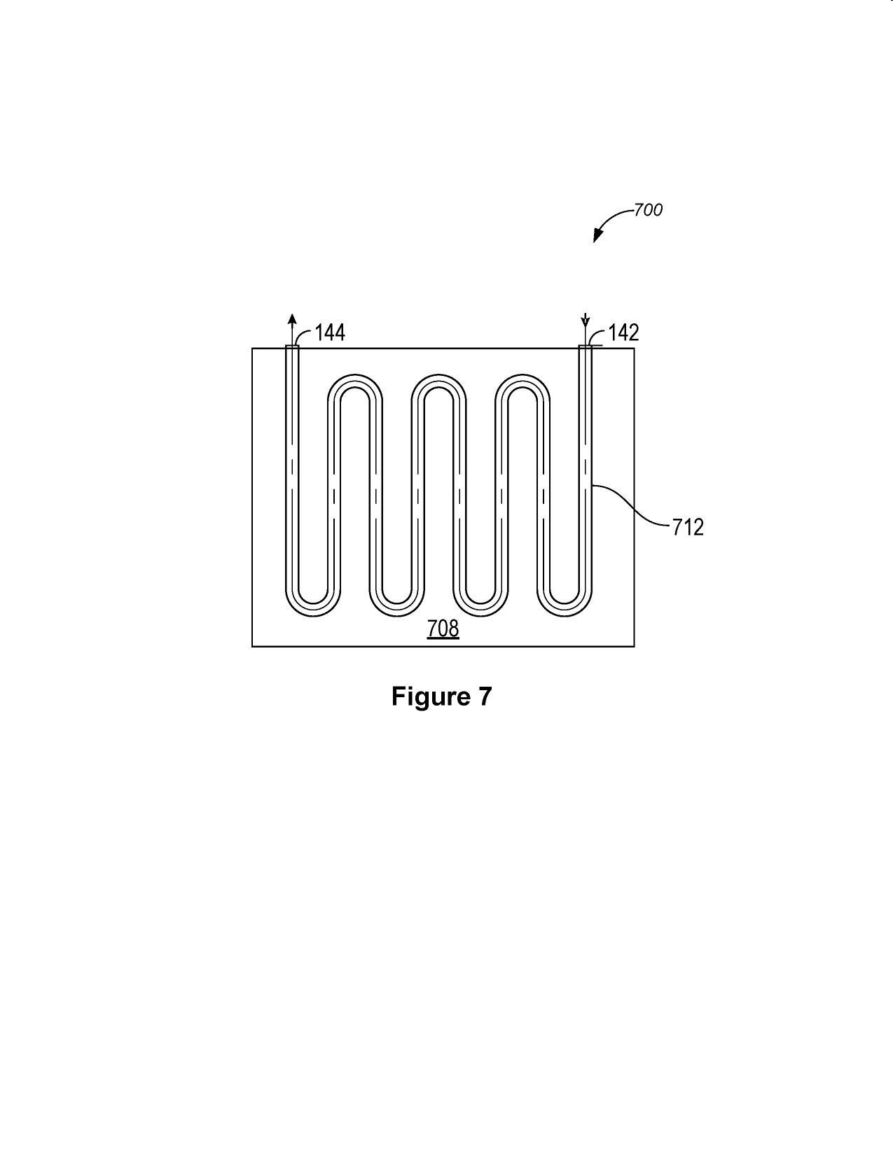

FIG. 7 is a schematic view of a cooling structure 700 applied by a rack server 120, in accordance with some embodiments. In some embodiments, the plurality of rack servers 120 include the first rack server 120-1 that further includes a cooling structure 700. In some embodiments, the cooling structure 700 is coupled to a subset of inlets 144 of the second coolant distribution manifold 302-2 and a subset of outlets 142 of the first coolant distribution manifold 302-1. Moreover, in some embodiments, the cooling structure 700 is configured to dissipate heat generated by the first rack server 120-1 by receiving a first coolant flow from the first coolant distribution manifold 302-1, circulating the first coolant flow through part of the first rack server 120-1, such as a lower surface of the first rack server 120-1 or an upper surface of the first rack server 120-1, and outputting the first coolant flow to the second coolant distribution manifold 302-2. In some embodiments, the cooling structure 700 is configured to dissipate heat generated by the first rack server 120-1 by receiving the first coolant flow from the first coolant distribution manifold 302-1, circulating the first coolant flow through part of the first rack server 120-1, such as the lower surface of the first rack server 120-1 and the upper surface of the second rack server 120-2 or the upper surface of the first rack server 120-1 and a lower surface of the second rack server 120-2, and outputting the first coolant flow to the second coolant distribution manifold 302-2, which allows for dissipating heat generated by the first rack server 120-1 and the second rack server 120-2.

In some embodiments, the cooling structure 700 is configured as a heat sink and/or a heat dissipator. For instance, in some embodiments, the cooling structure 700 includes a plate 708. In some embodiments, the plate 708 is configured to contact with a surface of the rack server 120 via a contact surface for absorbing the heat generated by the rack server 120. In some embodiments, the plate 708 includes one or more of admiralty brass, aluminum, aluminum brass, carbon steel, copper, cupronickel 70/30 and cupronickel 90/10, an alloy of nickel and copper (also called Monel alloys), stainless steel (e.g., duplex or super duplex grade), or a combination thereof. Further, in some embodiments, the plate 708 includes a channel 712 within an interior of the plate 708, which allows for flowing coolant through the interior of the plate 708 to transfer heat from the server rack 100 to plate 708 and ultimately to the coolant. For instance, referring briefly to FIG. 4B, in some embodiments, the channel 712 of the plate 708 is in fluidic communication with an inlet 144 of the first coolant distribution manifold 302-1 and an outlet 142 of the second coolant distribution manifold 302-2, which provides fluidic communication between the first coolant distribution manifold 302-1 and the second coolant distribution manifold 302-2 through the plate 708. In some embodiments, the coolant channel 712 includes a serpentine shape, which provides increased surface area for the channel to transfer heat between the plate 708 and the coolant flowing along the channel 712. Moreover, in some embodiments, the channel 712 extends substantially parallel to the contact surface of the rack server 120 from the inlet 144 of the first coolant distribution manifold 302-1 to the outlet 142 of the second coolant distribution manifold 302-2.

Additionally, in some embodiments, the plate 708 has a height greater than a threshold dimension, e.g., a first threshold dimension based on or greater than a length and/or a width of the plate 708, forming a metallic block. In some embodiments, the coolant channel 712 is configured to extend in three dimensions of the block. In some implementations, the coolant channel 712 extends along a plurality of parallel layers each of which is substantially parallel or perpendicular to the contact surface of the plate 708. Particularly, in an example not illustrated, the coolant channel 712 extends successively from a bottom layer adjacent and parallel to the contact surface to each upper layer above the bottom layer parallel to the contact surface.

Accordingly, in some embodiments, the server rack 100 further includes a cooling structure 700 disposed between two immediately adjacent slots 104 in the plurality of slots 104. Stated another way, in some embodiments, the cooling structure 700 is disposed under a lower end surface of a respective upper slot 104 or above an upper end surface of a respective lower slot 104, in which the upper slot 104 accommodates a first rack server 120-1 and the lower slot 104 accommodates a second rack server 120-2. As such, the cooling structure 700 is configured to at least partially carries away heat absorbed from immediately adjacent computing equipment modules 106 and/or rack servers 120 by the coolant flowing in the channel 712.

In some embodiments, the server rack 100 further includes a coolant distribution unit (CDU) 310. In some embodiments, the CDU 310 is disposed in a slot 104 of the plurality of slots 104 of the rack structure 102. However, the present disclosure is not limited thereto. For instance, referring briefly to FIG. 4A, in some embodiments, the CDU 310 is disposed on the supporting surface 304 of the base 150 associated with the rack structure 102, such that an entirety of the plurality of slots 104 is available for receiving one or more rack servers 120.

In some embodiments, the plurality of rack servers 120 includes N servers, in which N is an integer number greater than or equal to two. Moreover, in some embodiments, the server rack 100 includes a plurality of cooling structures 700, in which the plurality of cooling structures 700 includes M cooling structures 700, in which M is an integer number greater than or equal to one. Furthermore, in some embodiments, M is one less than N, which allows for disposing a respective cooling structure 700 interposing between adjacent rack servers 120 in the plurality of rack servers 120. In some embodiments, M it at most one less than N, which allows for disposing the respective cooling structure 700 interposing between adjacent pairs rack servers 120 in the plurality of rack servers 120 or the like. By way of example, in some embodiments, the plurality of rack servers 120 includes 42 rack servers 120, such that at most 41 cooling structures 700 is disposed interposing between two or more rack servers 120 in the plurality of rack servers 120. However, the present disclosure is not limited thereto.

In some embodiments, the CDU 310 is coupled to the first coolant distribution manifold 302-1 and the second coolant distribution manifold 302-2, which allows for the CDU 310 to circulate the coolant through both the first coolant distribution manifold 302-1 and the second coolant distribution manifold 302-2 via fluidic communication provided by the coupling with the CDU 310. For instance, in some embodiments, the CDU 310, the first coolant distribution manifold 302-1, and the second coolant distribution manifold 302-2 form a closed loop for flowing a first coolant from the CDU 310 through the first coolant distribution manifold 302-1 and receiving the first coolant by the second coolant distribution manifold 302-2 via the cooling structure 700. However, the present disclosure is not limited thereto. By way of example, in some embodiments, the first coolant distribution manifold 302-1 forms a first closed loop for circulating a first volume of the first coolant via the CDU 310 and the second coolant distribution manifold 302-2 forms a second closed loop for circulating a second volume of a second coolant via the CDU 310 different from the first coolant, thereby physically separating the first coolant of the first coolant distribution manifold 302-1 and second coolant of the second coolant distribution manifold 302-2. In some embodiments, the first coolant distribution manifold 302-1 forms the first closed loop for circulating the first volume of the first coolant via the CDU 310 and the second coolant distribution manifold 302-2 forms the second closed loop for circulating a second volume of the first coolant via the CDU 310, thereby physically separating the first closed loop of the first coolant distribution manifold 302-1 and second closed loop of the second coolant distribution manifold 302-2 while using a common coolant, such as a stream of coolant received by the CDU 310 from a reservoir 350 of coolant and bifurcated using the CDU 310 to the first coolant distribution manifold 302-1 and the second coolant distribution manifold 302-2. However, the present disclosure is not limited thereto.

In some embodiments, the CDU 310 is coupled to the first coolant distribution manifold 302-1 and the second coolant distribution manifold 302-2 via the two coolant tubes 312, such as a first coolant tube 312-1 and a second coolant tube 312-1 that are collectively configured to provide and collect the coolant flows via the CDU 310. By way of example, in some embodiments, the first coolant distribution manifold 302-1 is coupled to the first coolant tube 312-1 and the second coolant distribution manifold 302-2 is coupled to the second coolant tube 312-2. In some embodiments, the coolant tube 312 is flexible, which allows for configuring the coolant tube 312 to various rack servers 120.

Moreover, in some embodiments, the CDU 310 has a front surface 314. In some embodiments, the front surface 314 of the CDU 310 is disposed a front of the server rack 100 (e.g., faces forward). In some embodiments, the CDU 310 is disposed in proximity to the first front edge 140-1 and the second front edge 140-2 of the rack structure 102. Furthermore, in some embodiments, the CDU 310 further includes a rear surface 316 that opposes the front surface 304 of the CDU 310.

In some embodiments, the rear surface 316 of the CDU 310 further includes a coolant source interface. In some embodiments, the coolant source interface is configured to exchange a central coolant flow with a coolant source 380 (FIG. 3B), such as a reservoir 350 of coolant, which is configured to provide external cooling fluid to the CDU 310. For instance, in some embodiments, coolant heated by and/or circulated through the rack structure 102 is returned to a coolant source 380, such as a reservoir 350 external to the CDU 310. Referring briefly to FIG. 3B, in some embodiments, the coolant source interface includes an inlet 320 configured to receive coolant from a first reservoir 350-1 and an outlet 322 configured to provide heated coolant to the first reservoir 350-1 or a different reservoir 350-2. However, the present disclosure is not limited thereto.

In some embodiments, the rear surface 316 of the CDU 310 further includes a tube interface 324 (e.g., interface 324-1) that is configured to provide the coolant flows to the first coolant distribution manifold 302-1. In some embodiments, the tube interface 324 (e.g., interface 322-1) is further configured to collect the coolant flows, which is provided to the first coolant distribution manifold 302-1, from the second coolant distribution manifold 302-2. For instance, in some embodiments, the tube interface 324 is configured to fluidly couple an inlet 330 of the first coolant distribution manifold 302-1 with the CDU 310 and/or an outlet 332 of the second coolant distribution manifold 302-2 with the CDU 310. Furthermore, in some embodiments, the two coolant tubes 312 are coupled to the tube interface 324 and disposed within the one of the plurality of slots 104 of the rack structure 102. Accordingly, in some embodiments, the two coolant tubes 312 are configured to extend to the front surface (e.g., first front edge 140-1 and/or second front edge 140-2) of the rack structure 102 which allows for accessing the first coolant distribution manifold and the second coolant distribution manifold. Said otherwise, in some embodiments, the two coolant tubes 312 and the tube interface 324 allow for the CDU 310 to provide and/or receive fluid to the first coolant distribution manifold 302-1 and/or from the second coolant distribution manifold 302-2 using various configurations and/or orientations for the first coolant distribution manifold 302-1 and the second coolant distribution manifold 302-2.

In some embodiments, the rear surface 316 of the CDU further includes a first tube interface 324-1 coupled to one of the first coolant distribution manifold 302-1 and the second coolant distribution manifold 302-2. Furthermore, the front surface 314 of the CDU 310 further includes a second tube interface 324-1 coupled to the other one of the first coolant distribution manifold 302-1 and the second coolant distribution manifold 302-1. Accordingly, in some embodiments, the CDU 310 allows for providing coolant flow through the first distribution manifold 302-1 at either the front or the rear of the rack structure 102 and receiving the coolant flow from the second coolant distribution manifold 302- at the other of the front or the rear of the rack structure 102, which provides a compact form for the server rack 100, allowing for a variety of rack servers 120 to be disposed thereof.

In some embodiments, the CDU 310 further includes a coolant pump 408, which allows for circulating coolant flow through the first coolant distribution manifold 302-1 and/or the second coolant distribution manifold 302-2, such as by increasing a flow rate and/or pressure of the coolant flow. In some embodiments, the CDU 310 further includes a coolant controller 410 that is coupled to the coolant pump 408 such that the coolant controller 410 is in electronic communication with the coolant pump 408. In some embodiments, the coolant controller 410 is configured to control the coolant pump 408 to circulate a central coolant into the first coolant distribution manifold 302-1 and/or receive (e.g., collect) the central coolant from the second coolant distribution manifold 302-2, thereby transferring heat from the rack server 120 to the coolant circulated by the coolant pump 408. In some embodiments, the coolant pump 408 is fluidly coupled between an inlet 320 and an outlet 322 of the CDU 310. However, the present disclosure is not limited thereto. In some embodiments, the coolant controller 410 is coupled to the coolant pump 408, and configured to control the coolant pump 408 to circulate the coolant from the outlet 142 of the first distribution manifold 302-1 to the inlet 144 of the second distribution manifold 302-2 via the channel 712 of the cooling structure 700.

In some embodiments, the server rack 100 includes, or is coupled to, a plurality of panels configured to convert the server rack 100 to a server cabinet. However, the present disclosure is not limited thereto.

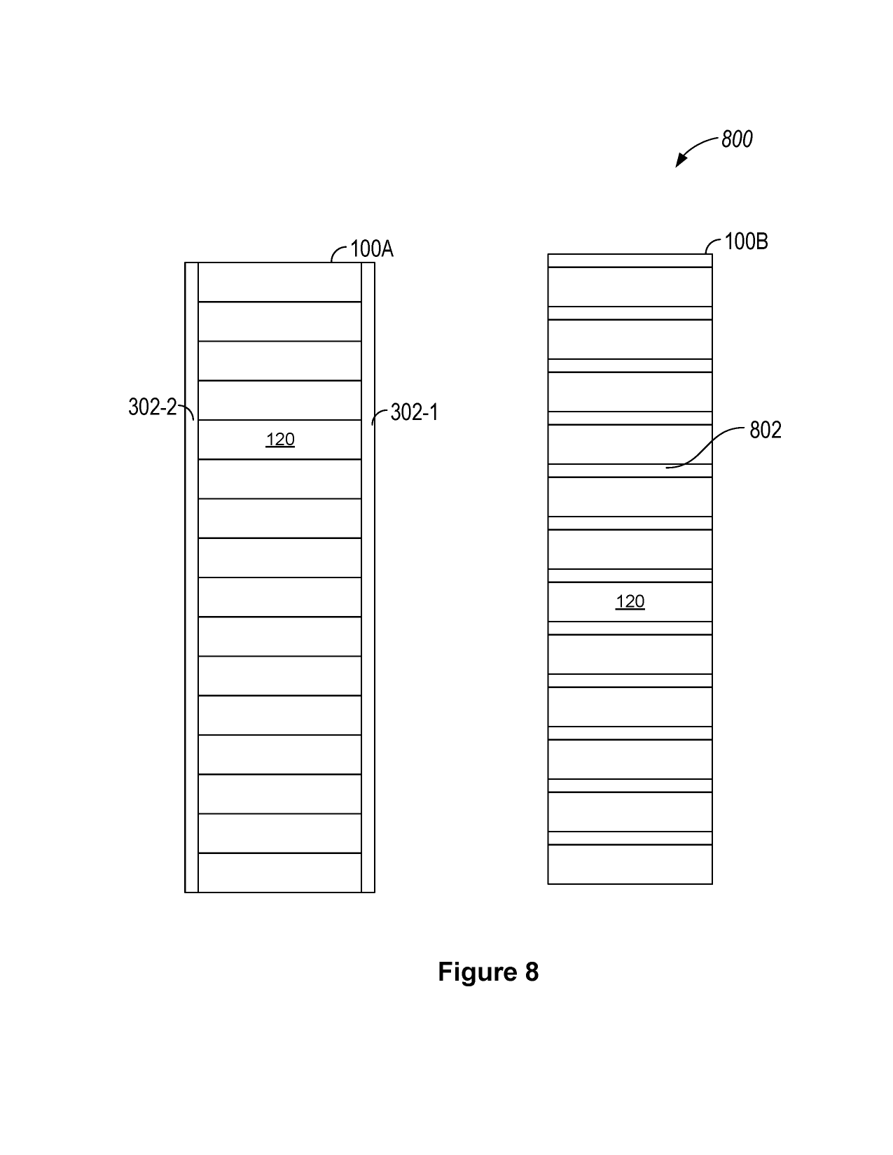

FIG. 8 is a schematic diagram comparing a first server rack 100A including front coolant manifolds (e.g., manifolds 302-1 and 302-2 in FIG. 3A) to a second server rack 100B, in accordance with some embodiments. Some implementations of a server rack 100 implement liquid cooling using a CDU 310 (FIGS. 3A-3D). Facility water connections are located at a hot aisle near a rear side of the server rack 100 in a data center. In some embodiments, in-rack piping and hoses are configured to connect from the rear side of the server rack 100 (e.g., server rack 100B). For liquid cooled servers 120, coolant tubes input/output may be located at the front of servers 120. The second sever rack 100B includes a plurality of cooling distribution modules (CDMs) 802 each of which is disposed between two equipment modules 106 (e.g., servers 120). The CDU 310 acts as an engine to drive coolant through a cooling system, allowing the coolant to be injected into an inlet of each CDM and collected from an outlet of each CDM. The CDU may regulate and control a flow of the coolant, and maintain desired temperature and flow rate. In some embodiments (FIG. 4A), the CDMs may be arranged in parallel to one another and coupled between an inlet and an outlet of the CDU.

In contrast, the first server rack 100A includes a first coolant manifold 302-1 and a second coolant manifold 302-2, and both manifolds 302-1 and 302-2 are disposed near the front edges. The first server rack 100A to utilizes side spaces between mounting rails and side panels for routing the coolant transfer hoses or tubes (e.g., tubes 312-1 and 312-2 in FIG. 3A). The coolant transfer hoses or tubes do not occupy any available rack space for computing node (e.g., servers 120), so that a computing density can be enhanced. It is noted that the coolant transfer hoses (e.g., tubes 312-1 and 312-2 in FIG. 3A) are not limited to any specific shape or form factor. FIGS. 3B-3E are merely some examples

In some embodiments, the equipment modules 106 (e.g., servers 120) are stack on each other in the first server rack 100A without being separated by, or leaving space to, the CDMs 802. Conversely, the second server rack 100B requires space among the equipment modules 106, so that the CDMs 802 can be accommodated. For example, a server rack 100 has a height of 48 rack units (e.g., 48 inches). Each server 120 has a height of 3 rack units, and each CDM has a height of 1 rack unit. If arranged according to the first server rack 100A, 16 servers can be accommodated within the height of 48 rack units. If arranged according to the second server rack 100B, 12 servers can be accommodated within the height of 48 rack units, leaving at least 11 one-inch spaces where 11 CDMs may be disposed, In other wors, the first server rack 100A can accommodate a larger number of servers 120 compared with the second server rack 100B.

In some embodiments, the coolant transfer hoses (e.g., tubes 312-1 and 312-2 in FIG. 3A) do not use any rack space that can be used for computing nodes in the first server rack 100A. Instead, the coolant transfer hoses (e.g., tubes 312-1 and 312-2 in FIG. 3A) utilize spaces between mounting rails and side panels, without impacting data center layout and deployment. In some embodiments, the coolant transfer hoses (e.g., tubes 312-1 and 312-2 in FIG. 3A) has a cross section that may be circular, oval, or rectangular with rounded edges.

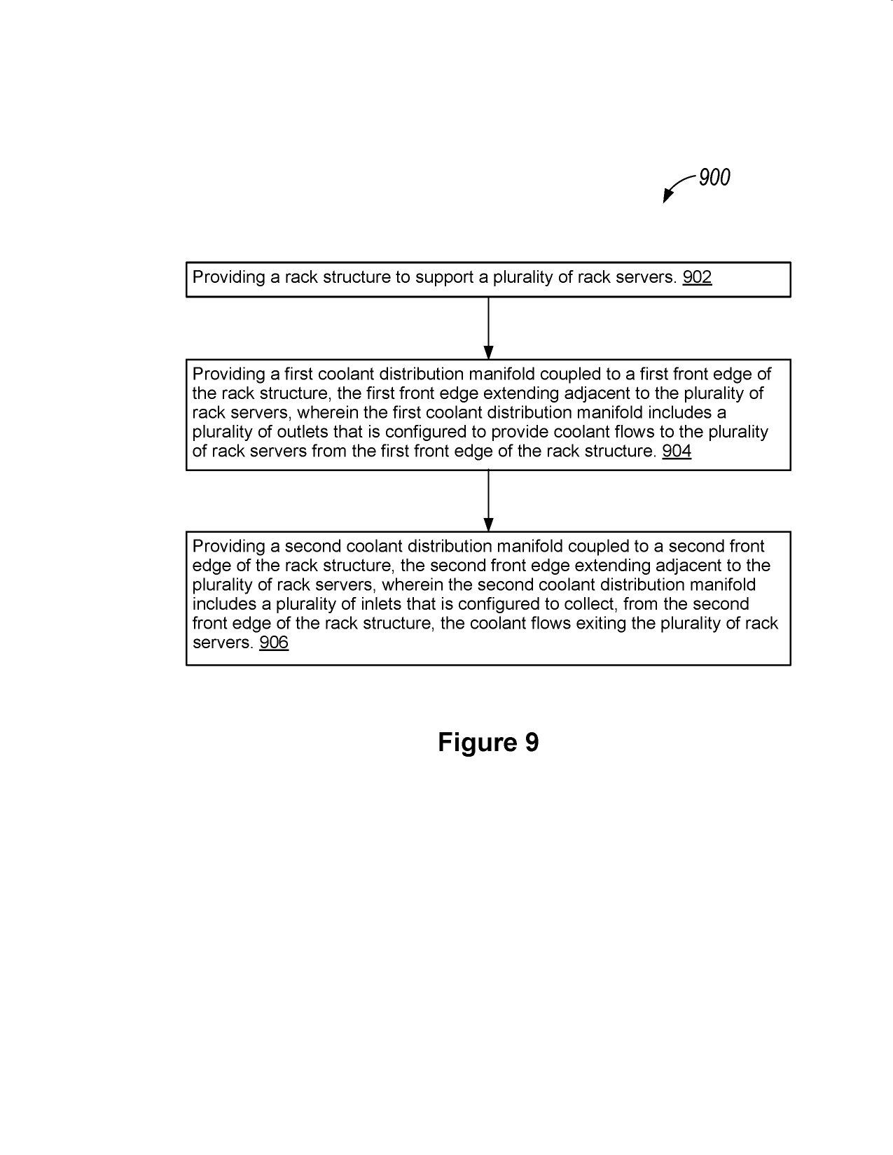

FIG. 9 is a flow diagram of an example method 900 for providing a server rack, in accordance with some embodiments. Now that a general topology of a server system 100 has been described in accordance with various embodiments of the present disclosures, details regarding some processes and methods of the present disclosure will be described with reference an example method 900 for controlling heat dissipation in a server system, such as server rack 100.

Block 902. Referring to block 902, in some embodiments, the method 900 includes providing a rack structure 102 to support a plurality of rack servers 120.

Block 904. Referring to block 904, in some embodiments, the method 900 further includes providing a first coolant distribution manifold 302-1 that is coupled to a first front edge 140-1 of the rack structure 102. In some embodiments, the first front edge 140-1 is configured to extend adjacent a surface associated with the plurality of rack servers 120. In some embodiments, the first coolant distribution manifold 302-1 includes a plurality of outlets 142 that is configured to provide coolant flows to the plurality of rack servers 120 from the first front edge 140-1 of the rack structure 102.

Block 906. Referring to block 906, in some embodiments, the method 900 includes providing a second coolant distribution manifold 302-2 that is coupled to a second front edge 140-2 of the rack structure 102. In some embodiments, the second front edge 140-2 is configured to extend adjacent to the plurality of rack servers 120. In some embodiments, the second coolant distribution manifold 302-2 includes a plurality of inlets 144 that is configured to collect from the second front edge 140-2 of the rack structure 102 the coolant flows exiting the plurality of rack servers 120.

Accordingly, the method 900 allows for dissipating heat generated by the plurality of rack servers 120 by providing cool fluid (e.g., coolant flow) from the first coolant distribution manifold 302-1 to the second coolant distribution manifold 302-2 via the plurality of rack servers 120.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A server rack, comprising:
a rack structure including a plurality of slots for receiving at least one or more rack servers;
a first coolant distribution manifold coupled to a first front edge of the rack structure, the first front edge extending adjacent to the plurality of slots, wherein the first coolant distribution manifold includes a plurality of outlets that is configured to provide coolant flows to the one or more rack servers from the first front edge of the rack structure; and
a second coolant distribution manifold coupled to a second front edge of the rack structure, the second front edge extending adjacent to the plurality of slots, wherein the second coolant distribution manifold includes a plurality of inlets that is configured to collect, from the second front edge of the rack structure, the coolant flows exiting the one or more rack servers.

2. The server rack of claim 1, wherein the rack structure is disposed on a supporting surface, and the first coolant distribution manifold and the second coolant distribution manifold extend in parallel with a direction that is substantially perpendicular to the supporting surface.

3. The server rack of claim 1, wherein the first front edge opposes the second front edge, and the plurality of slots is located between the first front edge and the second front edge of the rack structure.

4. The server rack of claim 1, wherein the first front edge is the second front edge, and the first coolant distribution manifold and the second coolant distribution manifold are disposed closely to one another on the same first front edge of the rack structure.

5. The server rack of claim 4, wherein the server rack includes a third coolant distribution manifold coupled to an opposite front edge, of the rack structure, distinct from the first front edge, and the third coolant distribution manifold is configured to provide supplemental coolant flows to the one or more rack servers.

6.The server rack of claim 4, wherein the server rack includes a fourth coolant distribution manifold coupled to an opposite front edge, of the rack structure, distinct from the first front edge, and the fourth coolant distribution manifold is configured to collect respective coolant flows from the one or more rack servers.

7. The server rack of claim 1, wherein the plurality of outlets is distributed substantially evenly on at least a portion of the first coolant distribution manifold, and the plurality of inlets is distributed substantially evenly on at least a portion of the second coolant distribution manifold.

8. The server rack of claim 1, further comprising:
a plurality of rack servers disposed in parallel between the first front edge and the second front edge of the rack structure, each rack server being received by a respective subset of the plurality of slots.

9. The server rack of claim 8, wherein at least two of the plurality of rack servers are disposed on two immediately adjacent slots of the rack structure, and include a first rack server and a second rack server, and wherein a bottom surface of the first rack server and a top surface of the second rack server has a distance that is smaller than a separation threshold.

10. The server rack of claim 8, wherein:
the plurality of rack servers include a first rack server, and the first rack server includes a cooling structure coupled to a subset of inlets of the second coolant distribution manifold and a subset of outlets of the first coolant distribution manifold;
the cooling structure is configured to dissipate heat generated by the first rack server by receiving a first coolant flow from the first coolant distribution manifold, circulating the first coolant flow through part of the first rack server, and outputting the first coolant flow to the second coolant distribution manifold.

11. The server rack of claim 8, wherein the plurality of rack servers include a plurality of graphics processing units (GPU) configured to implement machine learning operations.

12. The server rack of claim 1, further comprising:
a coolant distribution unit (CDU) disposed in one of the plurality of slots of the rack structure, wherein the CDU is coupled to the first coolant distribution manifold and the second coolant distribution manifold via two coolant tubes, and configured to provide and collect the coolant flows via the two coolant tubes, and wherein the CDU has a front surface facing forward and disposed in proximity to the first front edge and the second front edge of the rack structure.

13. The server rack of claim 12, wherein the CDU further includes a rear surface that opposes the front surface of the CDU, and the rear surface of the CDU further includes a coolant source interface configured to exchange a central coolant flow with a coolant source.

14. The server rack of claim 12, wherein the CDU further includes a rear surface that opposes the front surface of the CDU, and the rear surface of the CDU further includes a tube interface configured to provide the coolant flows to the first coolant distribution manifold and collect the coolant flows from the second coolant distribution manifold.

15. The server rack of claim 14, wherein the two coolant tubes are coupled to the tube interface and disposed within the one of the plurality of slots of the rack structure to extend to the front surface to access the first coolant distribution manifold and the second coolant distribution manifold.

16. The server rack of claim 12, wherein:
the CDU further includes a rear surface that opposes the front surface of the CDU;
the rear surface of the CDU further includes a first tube interface coupled to one of the first coolant distribution manifold and the second coolant distribution manifold;
the front surface of the CDU further includes a second tube interface coupled to the other one of the first coolant distribution manifold and the second coolant distribution manifold.

17. The server rack of claim 12, wherein the front surface of the CDU further includes a tube interface configured to provide the coolant flows to the first coolant distribution manifold and collect the coolant flows from the second coolant distribution manifold.

18. The server rack of claim 12, wherein the CDU further comprises:
a coolant pump;
a coolant controller coupled to the coolant pump, wherein the coolant controller is configured to control the coolant pump to push a central coolant into the first coolant distribution manifold and collect the central coolant from the second coolant distribution manifold.

19. A server system, comprising:
a plurality of rack servers;
a rack structure for supporting the plurality of rack servers;
a first coolant distribution manifold coupled to a first front edge of the rack structure, the first front edge extending adjacent to the plurality of rack servers, wherein the first coolant distribution manifold includes a plurality of outlets that is configured to provide coolant flows to the plurality of rack servers from the first front edge of the rack structure; and
a second coolant distribution manifold coupled to a second front edge of the rack structure, the second front edge extending adjacent to the plurality of rack servers, wherein the second coolant distribution manifold includes a plurality of inlets that is configured to collect, from the second front edge of the rack structure, the coolant flows exiting the plurality of rack servers.

20. A method for controlling heat dissipation in a server system, comprising:
providing a rack structure to support a plurality of rack servers;
providing a first coolant distribution manifold coupled to a first front edge of the rack structure, the first front edge extending adjacent to the plurality of rack servers, wherein the first coolant distribution manifold includes a plurality of outlets that is configured to provide coolant flows to the plurality of rack servers from the first front edge of the rack structure; and
providing a second coolant distribution manifold coupled to a second front edge of the rack structure, the second front edge extending adjacent to the plurality of rack servers, wherein the second coolant distribution manifold includes a plurality of inlets that is configured to collect, from the second front edge of the rack structure, the coolant flows exiting the plurality of rack servers.
